(19) United States
(12) Patent Application Publication
(10) Pub. No.: US 2016/0211777 A1
(43) Pub. Date: Jul. 21, 2016

(54) ENERGY GENERATING DEVICE USING TEMPERATURE VARIATION AND SENSOR FOR DETECTING TEMPERATURE VARIATION COMPRISING THE SAME

(71) Applicant: RESEARCH & BUSINESS FOUNDATION SUNGKYUNKWAN UNIVERSITY, Suwon-si (KR)

(72) Inventors: Sang-Woo KIM, Yongin-si (KR); Sung Soo KWAK, Seongnam-si (KR); Tae Yun KIM, Incheon (KR); Tae-Ho KIM, Seoul (KR); Wanchul SEUNG, Yongin-si (KR); Hanjun RYU, Daejeon (KR); Hong-Joon YOON, Goyang-si (KR); Ju Hyuck LEE, Suwon-si (KR)

(73) Assignee: RESEARCH & BUSINESS FOUNDATION SUNGKYUNKWAN UNIVERSITY, Suwon-si (KR)

(21) Appl. No.: 15/002,694

(22) Filed: Jan. 21, 2016

(30) Foreign Application Priority Data
Jan. 21, 2015 (KR) 10-2015-0010181

(51) Int. Cl. H02N 2/18; H01L 41/047; G01K 7/00; H01L 41/113

(52) U.S. Cl. CPC H02N 2/18; H01L 41/1132; H01L 41/047; G01K 7/00

(57) ABSTRACT

An energy generating device includes first material portions comprising a first material, wherein the first material is a piezoelectric material; second material portions comprising a second material, wherein the second material has a larger coefficient of thermal expansion than the first material; lower electrodes; and upper electrodes, wherein second material portions are spaced apart from one another, the first material portions are disposed in a space between the second material portions and in contact with the second material portion, and each of the lower electrodes and upper electrodes are disposed below and above, respectively, each of the first material portions.

### CROSS-REFERENCE TO RELATED APPLICATION

This application claims the benefit under 35 USC 119(a) of Korean Patent Application No. 10-2015-0010181 filed on Jan. 21, 2015 in the Korean Intellectual Property Office, the entire disclosure of which is incorporated herein by reference for all purposes.

### BACKGROUND

1. Field

The following description relates to an energy generating device that makes use of a piezoelectric material and also a material that has a larger coefficient of thermal expansion as compared with the piezoelectric material. Also, the following description relates to a sensor for detecting a temperature variation that uses the energy generating device to detect a temperature variation.

2. Discussion of Related Art

As the energy consumption surges in present day industry, active countermeasures to depletion of energy sources in the future, such as the development of alternative energy sources or effective use of waste energy, are required. In particular, the electric power generation from fossil fuels, which is currently being widely used, causes problems such as environmental pollution and depletion of natural resources. To overcome such problems, research and development on the materials that are capable of high-efficiency electric power generation are encouraged and actively ongoing in advanced countries, targeting the large-scale electric power generation by natural energy sources, such as solar heat or differences in ocean temperatures, and, especially, much research is in progress on the methods to maximize the Seebeck effect in which a voltage is produced by the temperature difference between both ends of a material. Korea has also researched materials for electric power generation in some institutions, but there has not been remarkable progress in terms of the materials.

Existing energy generating devices that take advantage of temperature differences are inappropriate for practical use, as substances such as lead or mercury, which are harmful to the human body, are used to manufacture the devices. Also, such devices are not useful enough because of their lack of ability to stretch. When a device that is stretchable and does not involve the use of lead is used, a low output of 0.3 mV and 3 pA was generated per 1 unit temperature change, which were too low for practical use.

Also, in the case of existing sensors for detecting a temperature variation, where the output voltage value of 2.44 mV/° C. per unit temperature change is used, a minute, or small, temperature variation does not result in much change in the value of an output voltage and, thus, is not detected by the sensors.

### SUMMARY OF THE INVENTION

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an energy generating device generates energy through a piezoelectric effect in response to a structural change that is induced by a temperature variation, and a sensor for detecting a temperature variation that uses the energy generating device to detect a temperature variation. The energy generating device includes first material portions comprising a first material, wherein the first material is a piezoelectric material; second material portions comprising a second material, wherein the second material has a larger coefficient of thermal expansion than the first material; lower electrodes; and upper electrodes, wherein second material portions are spaced apart from one another, the first material portions are disposed in a space between the second material portions and in contact with the second material portion, and each of the lower electrodes and upper electrodes are disposed below and above, respectively, each of the first material portions.

In another general aspect, an energy generating device includes first material portions comprising a first material, wherein the first material is a piezoelectric material; second material portions comprising a second material that has a larger coefficient of thermal expansion than the first material; lower electrodes; and upper electrodes, wherein the first material portions are inserted into an upper surface of the second material portions, and each one of the lower electrodes and upper electrodes is disposed below and above, respectively, each of the first material portions.

In another general aspect, a sensor for detecting a temperature variation, wherein the sensor includes an energy generating device including first material portions comprising a first material, wherein the first material is a piezoelectric material; second material portions comprising a second material that has a larger coefficient of thermal expansion than the first material; lower electrodes; upper electrodes, wherein the first material portions are inserted into an upper surface of the second material portions, and each one of the lower electrodes and upper electrodes is disposed below and above, respectively, each of the first material portions; and a voltmeter configured to measure a change in voltage generated by the energy generating device in response to a temperature variation, wherein the voltmeter is electrically connected between the upper electrodes and lower electrodes, and the sensor is configured to sense the temperature variation by the measured change in voltage.

Also, the sensor for detecting a temperature variation of the present invention can detect the degree of a temperature variation by measuring the electric current that is created in response to a minute variation in temperature.

Other features and aspects will be apparent from the following detailed description, the drawings, and the claims.

### BRIEF DESCRIPTION OF THE DRAWINGS

FIG. 1 is a side view of an example of an energy generating device;

FIG. 2 is a side view of another example of an energy generating device;

FIGS. 3A-3I illustrate a method of manufacturing an energy generating device;

FIG. 4 is an isometric view of an example of a conventional energy generating device;

FIG. 5 is a graph that compares the voltage variation that results upon variation in temperature of the example energy generating device and the conventional energy generating device;

FIG. 6A shows the distribution and directions of the loads generated in a piezoelectric body and the value of an output voltage by the piezoelectric effect, upon variation in temperature in the conventional energy generating device;

FIG. 6B shows the distribution and directions of the loads generated in a piezoelectric body and the value of an output voltage by the piezoelectric effect, upon variation in temperature in the example energy generating device;

FIG. 7A and FIG. 7B show the measured results of the change in the value of an output voltage with time at a particular degree of a temperature variation per unit time in the conventional energy generating device example and the example energy generating device; and

FIG. 8 is a graph that shows the values of an output voltage at various degrees of bending of the example energy generating device.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION OF EXEMPLARY EMBODIMENTS

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art. Unless indicated otherwise, a statement that a first layer is “on” a second layer or a substrate is to be interpreted as covering both a case where the first layer directly contacts the second layer or the substrate, and a case where one or more other layers are disposed between the first layer and the second layer or the substrate.

Words describing relative spatial relationships, such as “below”, “beneath”, “under”, “lower”, “bottom”, “above”, “over”, “upper”, “top”, “left”, and “right”, may be used to conveniently describe spatial relationships of one device or elements with other devices or elements. Such words are to be interpreted as encompassing a device oriented as illustrated in the drawings, and in other orientations in use or operation. For example, an example in which a device includes a second layer disposed above a first layer based on the orientation of the device illustrated in the drawings also encompasses the device when the device is flipped upside down in use or operation.

Terms such as “first” and “second” may be used to describe various elements of an embodiment, but the elements should not be limited to the terms. Such terms are used to merely distinguish one element from the other(s). For example, “the first element” may also be named “the second element,” and similarly, “the second element” may also be named “the first element,” without departing from the scope of the present invention.

The terms in the following description are used to merely describe particular embodiments and not intended to limit the claims. The expression in the singular form covers the expression in the plural form unless otherwise indicated. It will be understood that the terms such as “contain,” “containing,” “include,” “including,” “comprise,” “comprising,” “have” and “having” specify that the features, elements and the like disclosed herein are present, but the terms do not preclude the possibility that one or more other features, elements and the like are also present or can be introduced, within the scope of the present invention.

Unless defined otherwise, all terms, including technical or scientific terms, used herein have the same meaning as commonly understood by a person of ordinary skill in the technical field to which the present invention belongs. Generally used terms such as those defined in a dictionary shall be construed to have the same meaning in the context of the relevant art and, unless otherwise defined explicitly, not to have an idealistic or excessively formalistic meaning.

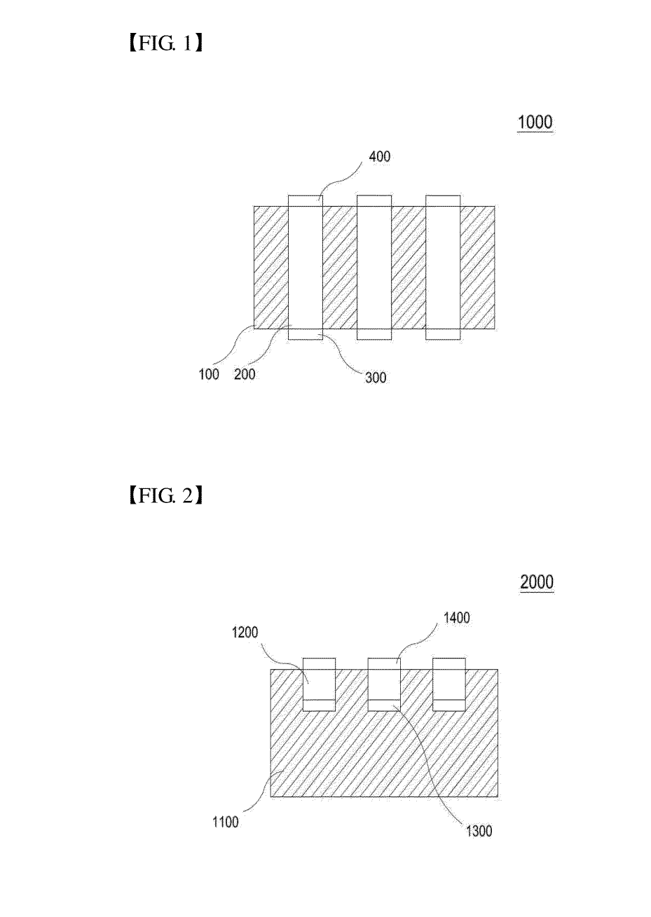

Referring to FIG. 1 the energy generating device 1000 includes one or more first material portions 200, a plurality of the second material portions 100, one or more lower electrodes 300, and one or more upper electrodes 400.

The first material portion 200 comprises a first material that contains a piezoelectric material, and there may be one or more of the first material portions present. The piezoelectric material is a material that generates electricity in response to a mechanical strain and is not limited to a certain material type; for example, it may be P(VDF-TrFE), PVDF, P(VDF-TrFE-CFE), PZT, PTO, BTO, BFO, KNbO₃, NaNbO₃, GeTe, ZnO, ZnSnO₃, or GaN. For example, the first material portion 200 may be made up of any one of the above piezoelectric materials or a combination thereof.

The second material portion 100 has a larger coefficient of thermal expansion as compared to the first material portion 200, and there may be a plurality of the second material portions present. In one embodiment, the coefficient of thermal expansion of the second material portion 100 is higher than that of the first material portion 200 by 2×10⁻⁴/° C. or more, and in this case, the piezoelectric effect is generated in the first material portion 200 by the expansive force of the second material portion 100. In other words, when the coefficient of thermal expansion of the second material portion 100 is greater than the coefficient of thermal expansion of the first material portion 200, the piezoelectric effect may be maximized, resulting in the creation of a large electric current. For example, the second material portion 100 comprises a second material and the first material portion 200 comprises a first material, wherein the second material has a larger coefficient of thermal expansion as compared to the first material.

The second material portions 100 are spaced apart from one another, and the first material portions 200 are disposed in the spaces between the second material portions 100 and are in contact with the second material portions 100. For example, each of the first material portions 200 are sandwiched between the second material portions 100.

The upper electrode 400 is disposed above the first material portion 200, one electrode for each of the first material portions, and there may be one or more of the upper electrodes present. In one example, the upper electrode 400 may have a two-dimensional nanostructure. Examples of the electrode with a two-dimensional nanostructure may include a nanowire and a nanorod. When a two-dimensional nanostructured electrode is used as the upper electrode 400, the energy device may be stretchable.

The lower electrode 300 is disposed below the first material portion 200, one electrode for each of the first material portions, and there may be one or more of the lower electrodes present. In one example, the lower electrode 300 may have a two-dimensional nanostructure. Examples of the electrode with a two-dimensional nanostructure may include a nanowire and a nanorod. When a two-dimensional nanostructured electrode is used as the lower electrode 300, the energy device may be stretchable.

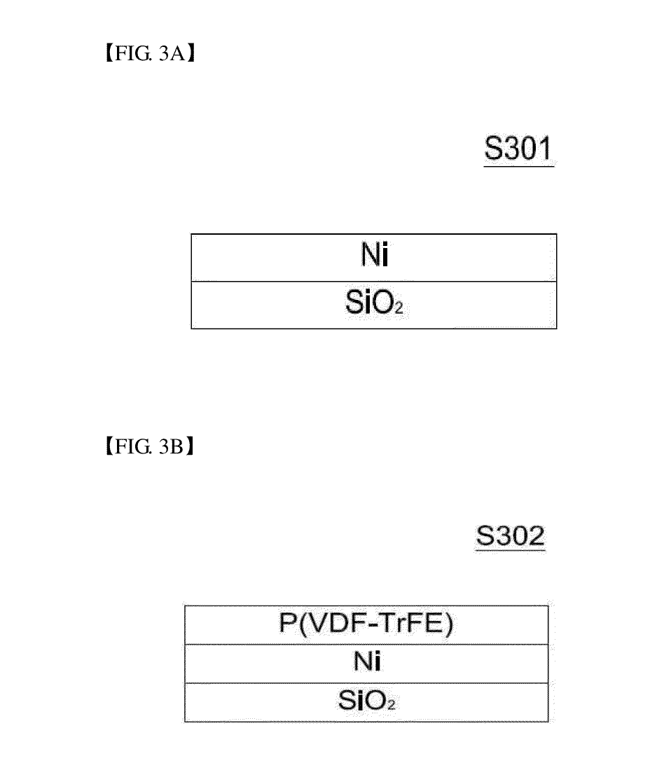

Referring to FIG. 2, the energy generating device 2000 includes a first material portion 1200, a second material portion 1100, a lower electrode 1300, and an upper electrode 1400.

The first material portion 1200 contains a piezoelectric material, and there may be one or more of the first material portions present. The piezoelectric material is a material that generates electricity in response to a mechanical strain and is not limited to a certain material type; for example, it may be P(VDF-TrFE), PVDF, P(VDF-TrFE-CFE), PZT, PTO, BTO, BFO, KNbO₃, NaNbO₃, GeTe, ZnO, ZnSnO₃, or GaN. For example, the first material portion 1200 may be made up of any one of the above piezoelectric materials or a combination thereof.

The second material portion 1100 has a larger coefficient of thermal expansion as compared to the first material portion 1200. In one embodiment, the coefficient of thermal expansion of the second material portion 1100 is higher than that of the first material portion 1200 by 2×10⁻⁴/° C. or more, and in this case, the piezoelectric effect is generated in the first material portion 1200 by the expansive force of the second material portion 1100. In other words, when the coefficient of thermal expansion of the second material portion 1100 is greater than the coefficient of thermal expansion of the first material portion 1200, the piezoelectric effect may be maximized, resulting in the creation of a large electric current. For example, the second material portion 1100 comprises a second material and the first material portion 200 comprises a first material, wherein the second material has a larger coefficient of thermal expansion as compared to the first material.

The first material portions 1200 are inserted into the upper surface of the second material portion 1100, spaced apart from one another, each of lower electrodes 1300 are disposed under each of the first material portions 1200, and each of upper electrodes 1400 are disposed above each of the first material portions 1200.

The upper electrodes 1400 are disposed above the first material portions 1200, one electrode for each of the first material portions, and there may be one or more upper electrodes 1400 present. The upper electrodes 1400 may have a two-dimensional nanostructure. Examples of two-dimensional nanostructure include a nanowire and a nanorod. When a two-dimensional nanostructured electrode is used as the upper electrode 1400, the energy device may be stretchable.

The lower electrode 1300 is disposed below the first material portions 1200, one electrode for each of the first material portions, and there may be one or more of the lower electrodes present. The lower electrode 1300 may have a two-dimensional nanostructure. Examples of the electrode with a two-dimensional nanostructure include a nanowire and a nanorod. When a two-dimensional nanostructured electrode is used as the lower electrode 1300, the energy device may be stretchable.

The sensor for detecting a temperature variation according to another embodiment includes an energy generating device and detects the degree of temperature variation by measuring the variation in the voltage that is generated from the energy generating device in response to the temperature variation.

The upper electrodes 1400 and lower electrodes 1300 are electrically connected with an external voltage measuring unit; for example, one or more wires that pass through the second material portion 1100 electrically connect the lower electrodes 1300 to the voltage measuring unit, and the upper electrodes 1400 and the voltage measuring unit are electrically connected to one another by one or more wires. For example, a voltmeter may be used as the voltage measuring unit.

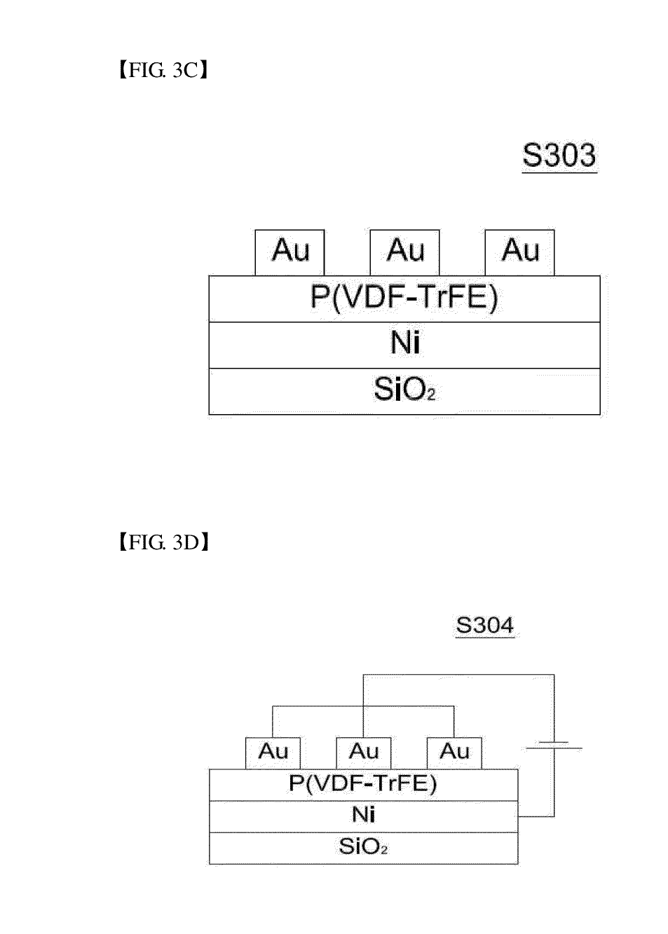

Referring to FIGS. 3A to 3I, a process for manufacturing the energy generating device is described below:

In process S301, a SiO₂ substrate with a nickel (Ni) thin film on top is provided.

In process S302, a first material portion is disposed on the Ni thin film layer of the SiO₂ substrate by applying a 20 wt % aqueous solution of P(VDF-TrFE) dropwise on the Ni thin film thereby coating the SiO₂ substrate with P(VDF-TrFE). The coating may be deposited by a spin coater through rotating the SiO₂ substrate at the rate of 1500 RPM for 30 seconds. Subsequently, the substrate is placed in an oven and heat-treated at 140° C. for 2 hours to set the first material portion.

In process S303, gold electrodes are disposed on the first material portion which spaced apart from one another at a constant distance. In this case, the distance is set at 200 nm.

In process S304, poling of the first material, is performed by applying 1 kV voltage to the gold electrode and Ni electrode. By the poling, dipole moments in P(VDF-TrFE) are arranged along the same direction.

In process S305, the portions in the P(VDF-TrFE) coating not covered by the gold electrodes are removed from the substrate by etching through 90 minutes of plasma treatment, which is carried out by injecting O₂ at a flow rate of 40 sccm and Ar at a flow rate of 20 sccm, as the plasma source gases.

In process S306, Polydimethylsiloxane (PDMS) is applied dropwise, and coating is performed by a spin coater at the rate of 500 RPM for 30 seconds to deposit a PDMS thermal expansion body. Through this operation, the spaces between the spaced-apart gold electrodes and the P(VDF-TrFE) are filled and coated with PDMS.

In process S307, the Ni thin film along with the P(VDF-TrFE), gold and PDMS that were coated on the Ni thin film are separated from the SiO₂ substrate by physical separation of the SiO₂ substrate from the Ni thin film.

In process S308, the Ni thin film is removed, by an etching solution, from P(VDF-TrFE), gold and PDMS.

In process S309, the materials from S308 are inverted so that PDMS is the lower substrate, and silver is deposited thereon. In this case, silver nanowires (AgNWs) are deposited as the silver material to create a stretchable upper electrode.

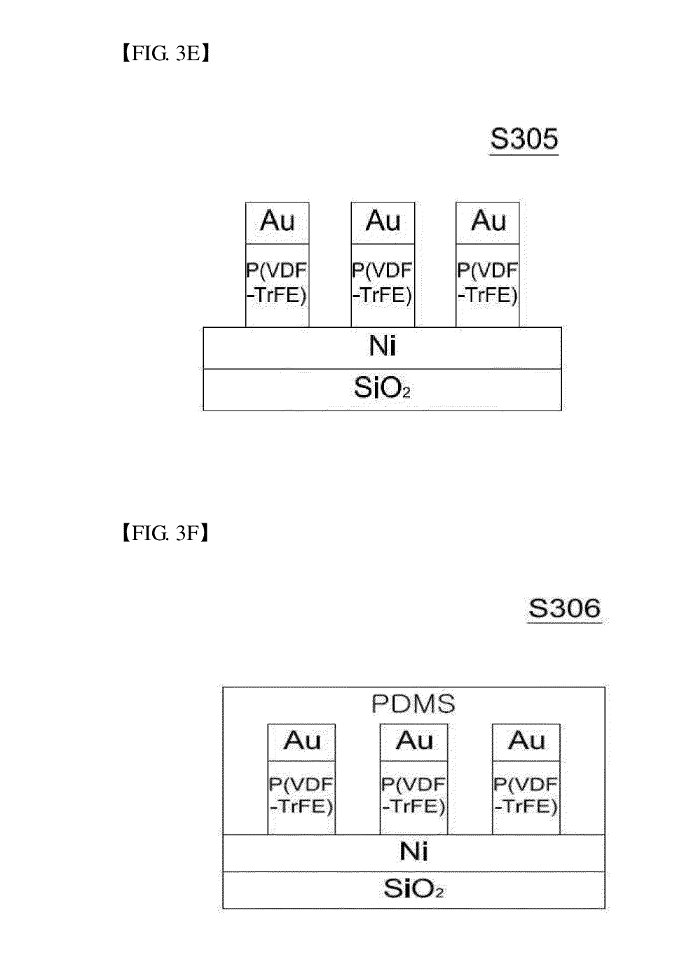

FIG. 4 shows the structure of a conventional energy generating device. Referring to FIG. 4, the conventional example includes a SiO₂ substrate, a lower electrode, the first material portion, and upper electrodes. The Ni lower electrode is deposited on the SiO₂ substrate, and then P(VDF-TrFE) is spin-coated, as the first material, on the Ni lower electrode to prepare the first material portion. Subsequently, gold (Au) is disposed as upper electrodes on the upper surface of the P(VDF-TrFE), wherein the electrodes are spaced apart from each another.

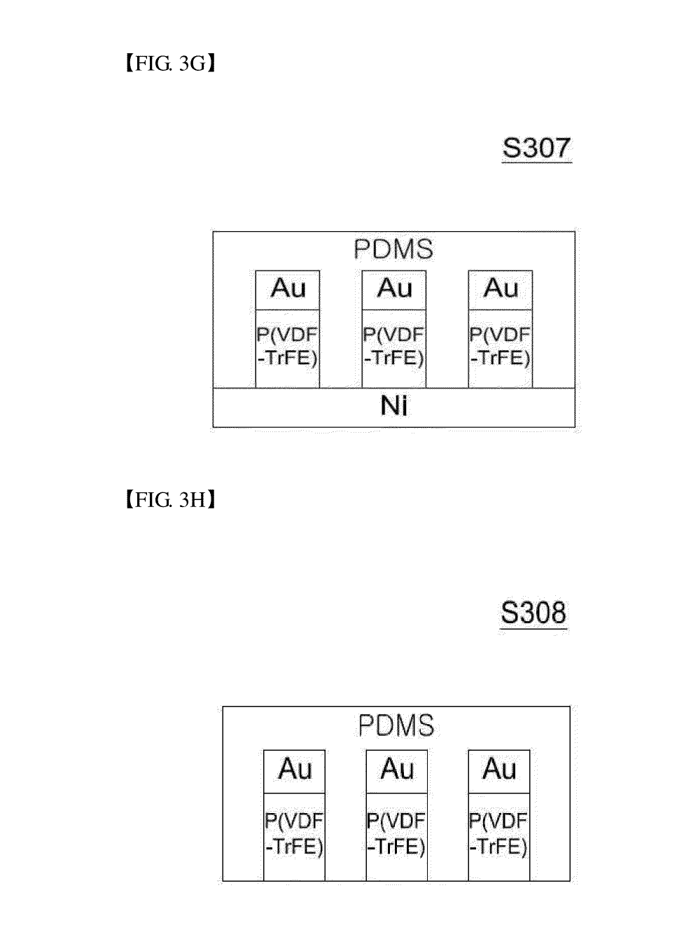

FIG. 5 is a graph that compares the voltage variation that results, upon variation in temperature, in the example of the present energy generating device and the conventional example. In FIG. 5, the first line (line 1) represents the voltage variation in the example of the present energy generating device, and the second line (line 2) represents the voltage variation in the conventional example.

Referring to FIG. 5, when the degree of temperature variation (ΔT) is 0.28, the difference in voltage variations of the example energy generating device versus conventional example is not large, but the difference increases as ΔT increases. Especially, when ΔT is 4.04, the voltage variation of the example energy generating device was about 100 mV, whereas the voltage variation of the conventional example was 18 mV. Thus, the voltage variation of the example energy generating device is larger than that of the conventional example by 82 mV at the same ΔT. Therefore, the voltage variation in response to temperature variation is greater in the example energy generating, as compared with the conventional example.

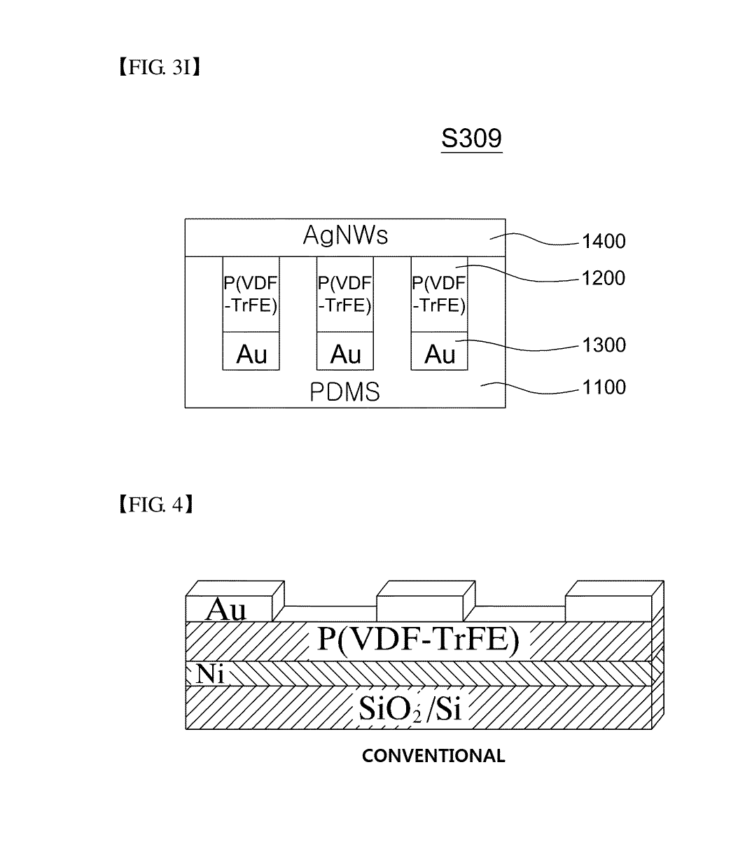

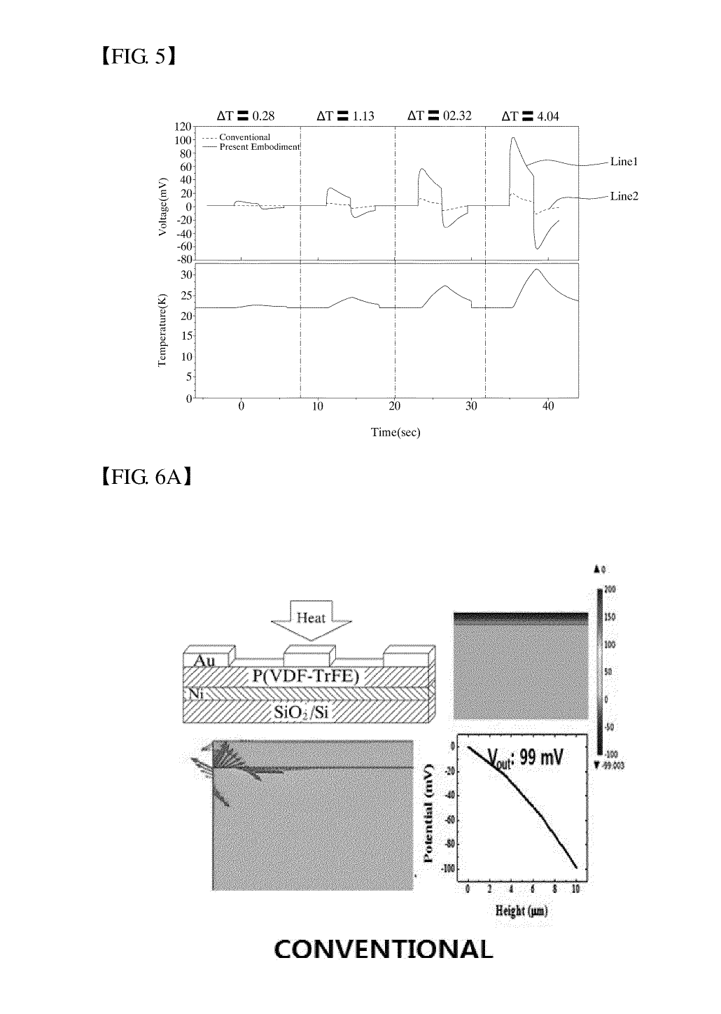

FIG. 6A shows the distribution and directions of the loads generated in the first material portion and value of an output voltage by the piezoelectric effect, upon variation in temperature in the conventional example, and FIG. 6B shows the distribution and directions of the loads generated in the first material portion and value of an output voltage by the piezoelectric effect, upon variation in temperature in an example of the present embodiment.

Referring to FIG. 6A and FIG. 6B, upon temperature variation of the conventional energy device, the distribution and directions of the loads are parallel to P(VDF-TrFE), the first material portion, in many cases (see FIG. 6A). Conversely, in the present embodiment, the distribution and directions of the loads are perpendicular to the P(VDF-TrFE), the first material portion, in many cases (see FIG. 6B). When the loads are applied perpendicularly to the first material, the magnitude of the loads generated in the first material portion is greater than when the loads are applied in a parallel manner, and thus, a greater voltage is generated. As seen in the graph of output voltage (potential) versus height in FIG. 6A, the value of the output voltage decreases with an increasing thickness, or height, in the first material portion and the value of the average output voltage is 99 mV. In contrast, the graph of output voltage (potential) versus height in FIG. 6B shows the value of the output voltage increases with an increasing height, or thickness, of the first material portion and the value of the average output voltage is 148.8 mV, which is 49.8 mV greater than the average output voltage, as measured versus height, of the conventional energy generating device (see FIG. 6A).

<Comparison of Example and Comparative Example in Terms of Output Voltage at Particular Degree of Temperature Variation Per Unit Time>

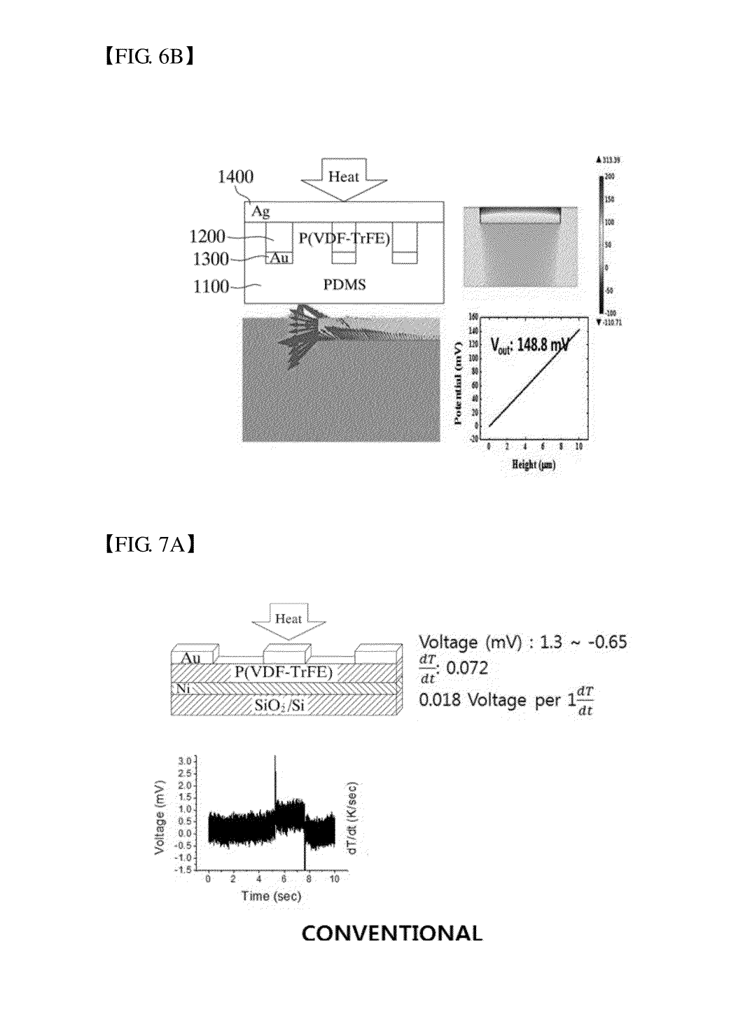

FIG. 7A and FIG. 7B show the change in the value of an output voltage as a function of the degree of variation in temperature per unit time in the conventional energy generating device and the example energy generating device, respectively.

Referring to FIG. 7A and FIG. 7B, the output voltage changes by 0.018 mV in the conventional energy generating device when the temperature changes at the rate of 0.072 K per second. Referring to the graph at the bottom of FIG. 7A, temperature variation does not cause much variation in the output voltage. Conversely, referring to the graph at the bottom of FIG. 7B, the output voltage changes by 0.042 mV when the temperature changes at the rate of 0.064 K per second and the variation in temperature results in the variation in the output voltage that is large enough to be seen with the naked eye. With this, the example energy generating device is able to function as a sensor for detecting a minute temperature variation because the change in the output voltage is large in response to a slight temperature variation.

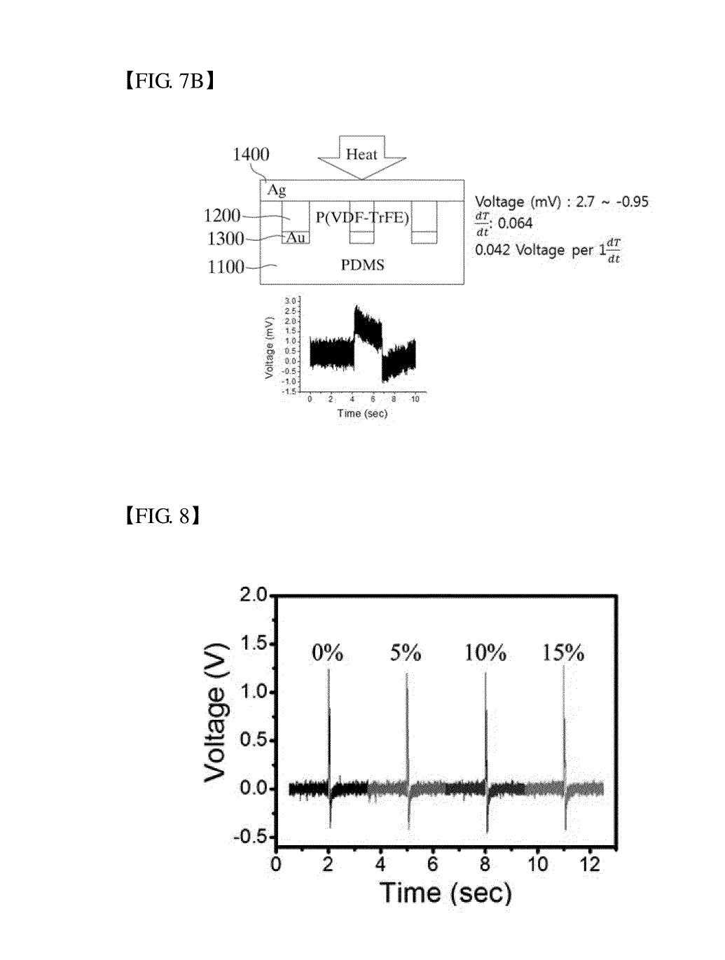

Referring to FIG. 8, comparing the values of an output voltage in response to temperature variation resulting in various degrees of bending (0%, 5%, 10%, 15%) of the energy generating device, the voltage is output at a substantially equal amount in response to temperature variation, regardless of the degree of bending. Judging by the graph in FIG. 8, the energy generating device, as described above, has a greater applicability in broad range of fields, such as in the field of displays, because it is stretchable and generates a sufficiently large output voltage.

As a non-exhaustive example only, a terminal/device/unit as described herein may be a mobile device, such as a cellular phone, a smart phone, a wearable smart device (such as a ring, a watch, a pair of glasses, a bracelet, an ankle bracelet, a belt, a necklace, an earring, a headband, a helmet, or a device embedded in clothing), a portable personal computer (PC) (such as a laptop, a notebook, a subnotebook, a netbook, or an ultra-mobile PC (UMPC), a tablet PC (tablet), a phablet, a personal digital assistant (PDA), a digital camera, a portable game console, an MP3 player, a portable/personal multimedia player (PMP), a handheld e-book, a global positioning system (GPS) navigation device, or a sensor, or a stationary device, such as a desktop PC, a high-definition television (HDTV), a DVD player, a Blu-ray player, a set-top box, or a home appliance, or any other mobile or stationary device capable of wireless or network communication. In one example, a wearable device is a device that is designed to be mountable directly on the body of the user, such as a pair of glasses or a bracelet. In another example, a wearable device is any device that is mounted on the body of the user using an attaching device, such as a smart phone or a tablet attached to the arm of a user using an armband, or hung around the neck of the user using a lanyard.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An energy generating device comprising:
first material portions comprising a first material, wherein the first material is a piezoelectric material;
second material portions comprising a second material, wherein the second material has a larger coefficient of thermal expansion than the first material;
lower electrodes; and
upper electrodes,
wherein second material portions are spaced apart from one another, the first material portions are disposed in a space between the second material portions and in contact with the second material portion, and each of the lower electrodes and upper electrodes are disposed below and above, respectively, each of the first material portions.

2. The energy generating device of claim 1, wherein one or more electrodes among the upper electrodes and lower electrodes have a two-dimensional structure.

3. The energy generating device of claim 1, wherein the first material portions are poled.

4. An energy generating device comprising:
first material portions comprising a first material, wherein the first material is a piezoelectric material;
second material portions comprising a second material that has a larger coefficient of thermal expansion than the first material;
lower electrodes; and
upper electrodes,
wherein the first material portions are inserted into an upper surface of the second material portions, and each one of the lower electrodes and upper electrodes is disposed below and above, respectively, each of the first material portions.

5. The energy generating device of claim 4, wherein an electrode among the upper electrodes and lower electrodes has a two-dimensional structure.

6. The energy generating device of claim 4, wherein the first material portions are poled.

7. A sensor for detecting a temperature variation, the sensor comprising:
the energy generating device of claim 1; and
a voltmeter configured to measure a change in voltage generated by the energy generating device in response to a temperature variation,
wherein the voltmeter is electrically connected between the upper electrodes and lower electrodes, and the sensor is configured to sense the temperature variation by the measured change in voltage.

8. A sensor for detecting a temperature variation comprising an energy generating device comprising:
first material portions comprising a first material, wherein the first material is a piezoelectric material;
second material portions comprising a second material that has a larger coefficient of thermal expansion than the first material;
lower electrodes;
upper electrodes,
wherein the first material portions are inserted into an upper surface of the second material portions, and each one of the lower electrodes and upper electrodes is disposed below and above, respectively, each of the first material portions; and
a voltmeter configured to measure a change in voltage generated by the energy generating device in response to a temperature variation,
wherein the voltmeter is electrically connected between the upper electrodes and lower electrodes, and the sensor is configured to sense the temperature variation by the measured change in voltage.
